(19) United States
(12) Patent Application Publication
(10) Pub. No.: US 2022/0084886 A1
(43) Pub. Date: Mar. 17, 2022

(54) WAFER PROCESSING METHOD

(71) Applicant: DISCO CORPORATION, Tokyo (JP)

(72) Inventor: Minoru SUZUKI, Tokyo (JP)

(21) Appl. No.: 17/447,468

(22) Filed: Sep. 13, 2021

(30) Foreign Application Priority Data
Sep. 16, 2020 (JP) 2020-155652

(51) Int. Cl. H01L 21/78; H01L 21/02

(52) U.S. Cl. CPC H01L 21/78; H01L 21/02076

(57) ABSTRACT

A wafer processing method includes applying a laser beam to division lines in a wafer to remove a passivation film laminated on the division lines and expose a semiconductor substrate along the division lines, thereafter coating a front surface of the wafer with a resin to form a protective film, and applying a laser beam to division lines to remove the protective film laminated on the division lines. Next, the semiconductor substrate is exposed along the division lines, after which the semiconductor substrate exposed along the division lines is divided by plasma etching with the protective film as a shielding film.

### BACKGROUND OF THE INVENTION

### Field of the Invention

The present invention relates to a processing method for dividing a wafer into chips by plasma etching.

### Description of the Related Art

A processing method has been known in which a water-soluble resin is applied onto a passivation film of a wafer formed with the passivation film on a front surface thereof to form a water-soluble resin film, a laser beam is applied from the side of the water-soluble resin film to remove the water-soluble resin film and the passivation film formed on division lines, thereby forming a mask, and thereafter, plasma etching is conducted from the front surface side to divide the wafer into individual chips (see, for example, Japanese Patent Laid-open No. 2019-071333 and Japanese Patent Laid-open No. 2018-006587).

### SUMMARY OF THE INVENTION

However, when it is intended to remove the water-soluble resin film and the passivation film through the water-soluble resin film, the laser beam is scattered by a component contained in the water-soluble resin, and unintended regions of the passivation film would be processed and peeled off by the scattered light. In addition, the laser output by which the water-soluble resin can be processed is too strong to process the passivation film. Therefore, when it is intended to remove the passivation film through the water-soluble resin, light transmitted through the water-soluble resin to be applied to the passivation film is generated, and the passivation film would be peeled off due to the heat of the transmitted light.

Accordingly, it is an object of the present invention to provide a wafer processing method with which, in dividing a wafer formed with a passivation film by plasma etching, the possibility that the passivation film may be peeled off due to scattered light or transmitted light can be restrained.

In accordance with an aspect of the present invention, there is provided a wafer processing method for dividing a wafer including a semiconductor substrate having a plurality of devices formed on a front surface thereof in regions partitioned by a plurality of intersecting division lines, into individual device chips, the semiconductor substrate having a passivation film laminated on the front surface thereof. The wafer processing method includes a passivation film removing step of applying a laser beam to the division lines to remove the passivation film laminated on the division lines and expose the semiconductor substrate along the division lines; a protective film forming step of coating the front surface of the wafer with a resin to form a protective film, after the passivation film removing step; a protective film removing step of applying a laser beam to the division lines to remove the protective film laminated on the division lines and expose the semiconductor substrate along the division lines, after the protective film forming step; and a dividing step of dividing the semiconductor substrate exposed along the division lines by plasma etching with the protective film coating the devices as a shielding film, after the protective film removing step.

Preferably, the resin that is in a liquid form and used in the protective film forming step is a water-soluble resin, and the wafer processing method further includes a protective film cleaning step of cleaning with water and removing the protective film coating the devices, after the dividing step.

Preferably, the passivation film is any of an SiO₂ film, a nitride film, and a polyimide film, the semiconductor substrate is a silicon substrate, and a gas used in the plasma etching is a fluorine-based gas.

According to the present invention, in dividing the wafer formed with the passivation film by plasma etching, the possibility that the passivation film may be peeled off due to scattered light or transmitted light can be restrained.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a flow chart depicting an example of a processing procedure of a wafer processing method according to an embodiment of the present invention;

FIG. 2 is a perspective view depicting an example of a wafer to be processed in the wafer processing method of FIG. 1;

FIG. 3 is a sectional view depicting a passivation film removing step and a protective film forming step of FIG. 1;

FIG. 4 is a sectional view depicting the passivation film removing step of FIG. 1;

FIG. 5 is a sectional view depicting the protective film forming step of FIG. 1;

FIG. 6 is a sectional view depicting a protective film removing step, a dividing step, and a protective film cleaning step of FIG. 1;

FIG. 7 is a sectional view depicting the protective film removing step of FIG. 1;

FIG. 8 is a sectional view depicting the dividing step of FIG. 1; and

FIG. 9 is a sectional view depicting the protective film cleaning step of FIG. 1.

### DETAILED DESCRIPTION OF THE PREFERRED EMBODIMENT

An embodiment of the present invention will be described in detail below referring to the drawings. The present invention is not limited by the contents described in the following embodiment. In addition, the component elements described below include those which can easily be conceived by a person skilled in the art and those which are substantially the same. Further, the configurations described below may be combined, as required. Besides, various kinds of omission, replacement, or modification of the configurations are possible within such a range as not to depart from the gist of the present invention.

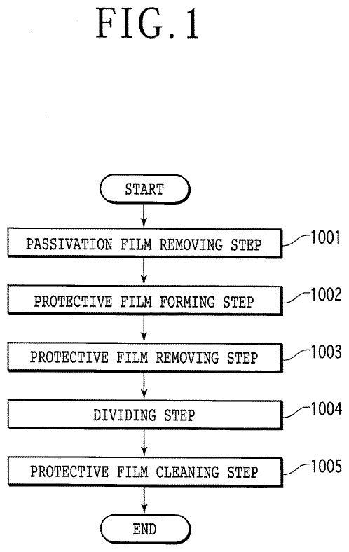

A wafer processing method according to the embodiment of the present invention will be described based on the drawings. The wafer processing method according to the embodiment includes, as depicted in FIG. 1, a passivation film removing step 1001, a protective film forming step 1002, a protective film removing step 1003, a dividing step 1004, and a protective film cleaning step 1005.

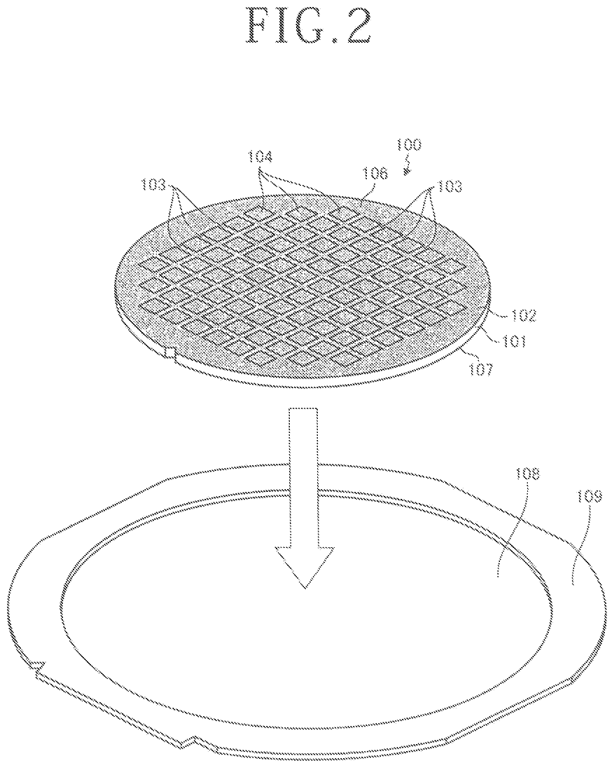

A wafer 100 to be processed in the wafer processing method according to the present embodiment has a disk-shaped semiconductor substrate 101 containing silicon as a base material. As depicted in FIG. 2, the wafer 100 has chip-size devices 104 formed in regions partitioned by a plurality of division lines 103 formed in a grid pattern on a front surface 102 of the semiconductor substrate 101. Note that the semiconductor substrate 101 of the wafer 100 is not limited to this example in the present invention, and sapphire, silicon carbide (SiC), and gallium arsenide, for example, may be used as the base material.

As depicted in FIG. 2, the semiconductor substrate 101 including the devices 104 has a passivation film 106 laminated on the whole area of the front surface 102 thereof. The passivation film 106 is lower than the semiconductor substrate 101 in etching rate in plasma etching to be carried out in the dividing step 1004 described later; for example, the etching rate of the passivation film 106 is equal to or less than 1/10 of that of the semiconductor substrate 101 in many cases. In the present embodiment in which the semiconductor substrate 101 formed thereon with the devices 104 is a silicon substrate, the passivation film 106 is any one of an SiO₂ film, a nitride film, and a polyimide film. In this case, the etching rate is on the order of 1/700 to 1/100 of that of the silicon substrate. The passivation film 106 is laminated, for example, by a plasma chemical vapor deposition (CVD) method, and protects the devices 104 from external contamination or intrusion of impurities or the like. In addition, the passivation film 106 may function as an insulating film, and a low-k film including an inter-layer insulating film material having a low dielectric constant is also one kind of the passivation film 106. Note that the passivation film 106 is not limited to this example in the present invention, and films of various compounds are used according to the base material of the semiconductor substrate 101.

In the present embodiment, as depicted in FIG. 2, the wafer 100 has an adhesive tape 108 attached to a back surface 107 on an opposite side to the front surface 102, with an annular frame 109 mounted to a peripheral edge of the adhesive tape 108, and processing in each step is conducted, but the present invention is not limited to this. The wafer 100 may be held by only the adhesive tape 108 without using the annular frame 109, or the wafer 100 may be held by a substrate made of glass, silicon, or the like through an adhesive material such as wax.

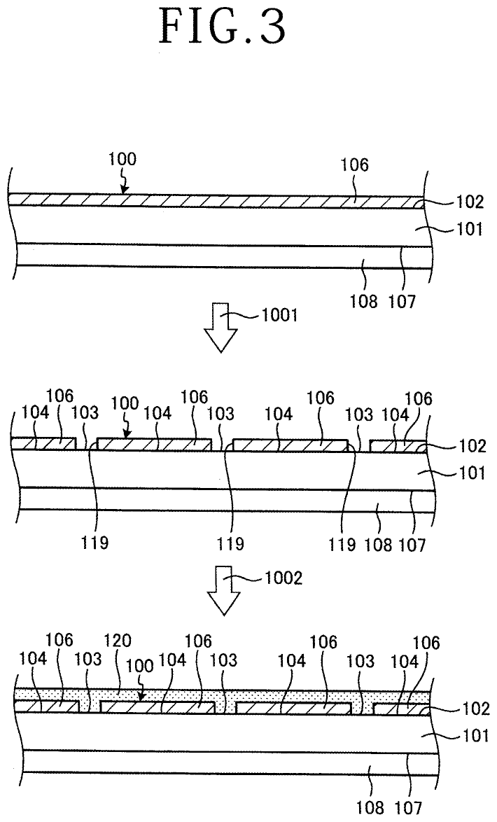

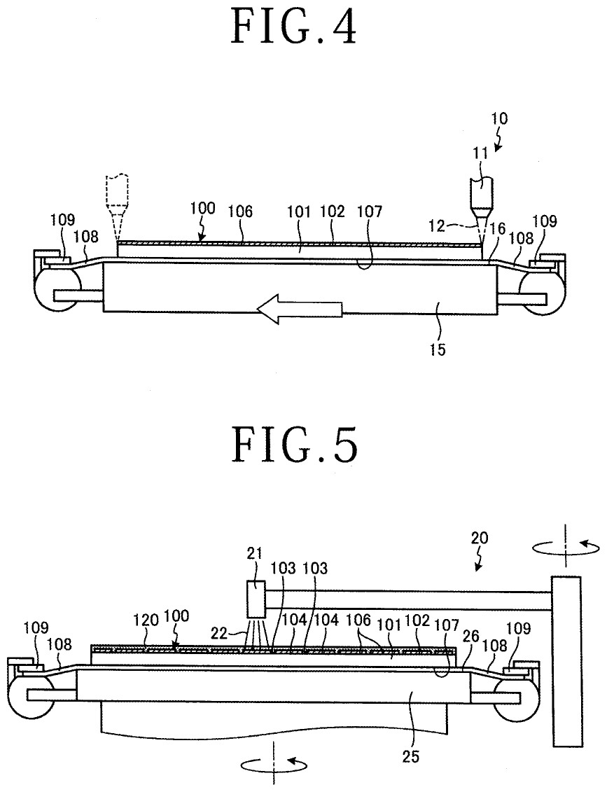

As illustrated in FIGS. 3 and 4, the passivation film removing step 1001 is a step of applying a laser beam 12 to the division lines 103 by a laser processing apparatus 10 to remove the passivation film 106 laminated on the division lines 103 and expose the semiconductor substrate 101 along the division lines 103.

In the passivation film removing step 1001, first, the adhesive tape 108 is attached to the back surface 107 of the wafer 100, and the back surface 107 side of the wafer 100 is held on a holding surface 16 of a holding table 15 of the laser processing apparatus 10 through the adhesive tape 108. Here, the holding table 15 in the present embodiment includes, for example, a disk-shaped frame body formed with a recess and a disk-shaped suction section fitted in the recess and formed from a porous ceramic having multiplicity of pores, and an upper surface of the suction section serves as the holding surface 16 that holds the wafer 100 under suction by a negative pressure introduced from a suction source (not illustrated).

In the passivation film removing step 1001, next, as depicted in FIG. 4, while a laser beam 12 of such a wavelength as to be absorbed in the passivation film 106 is emitted by a laser oscillator 11 of the laser processing apparatus 10 to be applied to the passivation film 106, the laser beam 12 and the wafer 100 formed thereon with the passivation film 106 are moved relative to each other along the division lines 103, for example, by a moving unit (not illustrated) for moving the holding table 15 in a direction parallel to the front surface 102 of the wafer 100 relative to the laser oscillator 11, so that what is generally called ablation of subliming or evaporating the passivation film 106 on the division lines 103 by the laser beam 12 is conducted, to thereby remove the passivation film 106 laminated on the division lines 103. In the passivation film removing step 1001, as a result, as depicted in FIG. 3, processed grooves 119 in a depth corresponding to the thickness of the passivation film 106 are formed along the division lines 103.

In the passivation film removing step 1001, for example, the pulsed laser beam 12 is applied to the passivation film 106 by the laser oscillator 11 of the laser processing apparatus 10. In the passivation removing step 1001, ablation is conducted on each of the division lines 103, so that, as depicted in FIG. 3, the passivation film 106 laminated on the division lines 103 is removed along all the division lines 103.

A protective film forming step 1002 is a step, as depicted in FIGS. 3 and 5, of applying a resin 22 to the front surface 102 of the wafer 100 by a resin supply apparatus 20 to form a protective film 120, after the passivation film removing step 1001.

In the protective film forming step 1002, first, the back surface 107 side of the wafer 100 is held on a holding surface 26 of a holding table 25 of the resin supply apparatus 20 through the adhesive tape 108. The holding table 25 is similar in structure to the holding table 15. In the protective film forming step 1002, next, as depicted in FIG. 5, during rotation of the holding table 25 holding the wafer 100, a liquid resin 22 is supplied by a nozzle 21 of the resin supply apparatus 20 to the vicinity of the center of the front surface 102 of the wafer 100, so that the liquid resin 22 thus supplied is extended on the front surface 102 of the wafer 100 by a centrifugal force at the time of rotation of the holding table 25, to thereby form a protective film 120 of the resin 22 coating the front surface 102 of the wafer 100. In the protective film forming step 1002, thereafter, a laminating treatment of further laminating the protective film 120 on the protective film 120 to obtain a thickness necessary at the time of plasma etching corresponding to the dividing step 1004 described later, and a curing treatment of curing the protective film 120 by heating or the like may be performed. The liquid resin 22 used in the protective film forming step 1002 is a water-soluble resin; in the present embodiment, it is, for example, polyvinyl alcohol (PVA), polyvinyl pyrrolidone (PVP), or the like. The protective film 120 functions as a shielding film (mask) for preventing the passivation film 106 and the semiconductor substrate 101 from being removed by plasma etching in the dividing step 1004 to be carried out afterwards.

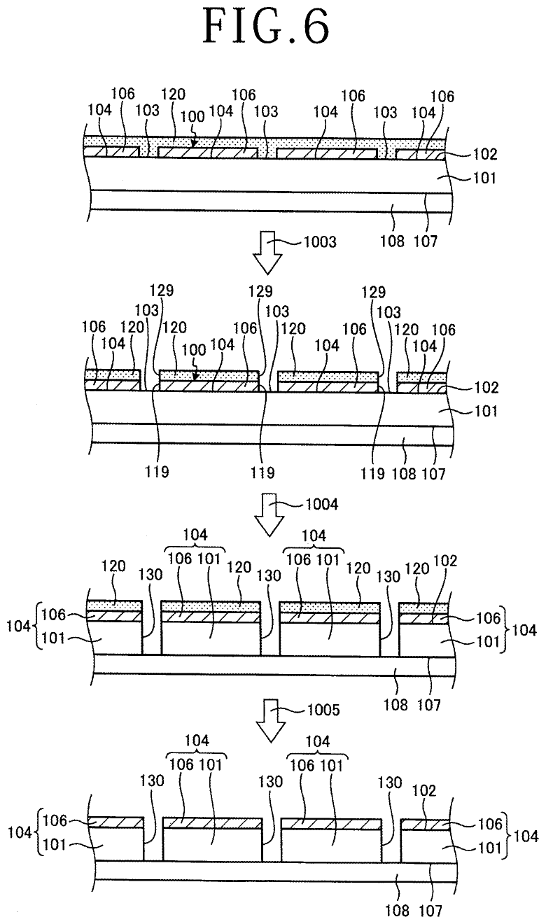

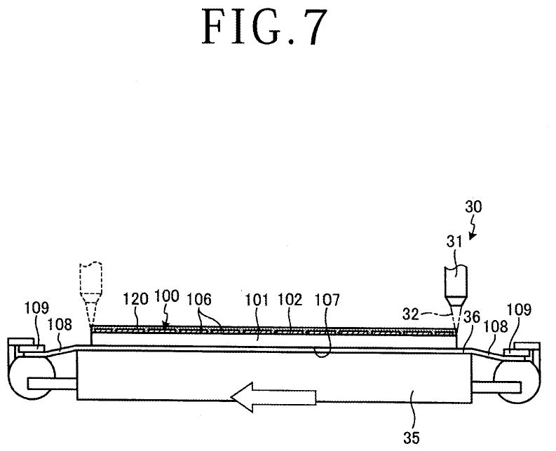

The protective film removing step 1003, as depicted in FIGS. 6 and 7, is a step of applying a laser beam 32 to the division lines 103 by a laser processing apparatus 30 to remove the protective film 120 laminated on the division lines 103 and expose the semiconductor substrate 101 along the division lines 103, after the protective film forming step 1002.

In the protective film removing step 1003, first, the back surface 107 side of the wafer 100 is held on a holding surface 36 of a holding table 35 of the laser processing apparatus 30 through the adhesive tape 108. The holding table 35 is similar in structure to the holding surface 15. In the protective film removing step 1003, next, as depicted in FIG. 7, while a laser beam 32 of such a wavelength as to be absorbed in the protective film 120 (resin 22) is emitted by a laser oscillator 31 of the laser processing apparatus 30 to be applied to the protective film 120, for example, the laser beam 32 and the wafer 100 formed thereon with the protective film 120 are moved relative to each other along the division lines 103, by a moving unit (not illustrated) for moving the holding table 35 in a direction parallel to the front surface 102 of the wafer 100 relative to the laser oscillator 31, so that what is generally called ablation of subliming or evaporating the protective film 120 on the division lines 103 by the laser beam 32 is conducted, to thereby remove the protective film 120 laminated on the division lines 103. In the protective film removing step 1003, as a result, as depicted in FIG. 6, processed grooves 129 where the protective film 120 has been removed are formed along the division lines 103. The protective film removing step 1003 is conducted by a method similar to the method for the passivation film removing step 1001, except for the application of the laser beam 32 of such a wavelength as to be absorbed in the protective film 120.

Note that, in a case where a test element group (TEG) as an evaluation element for the devices 104 is provided on the division lines 103 of the wafer 100, the TEG, formed of a metal, may act as a shielding film in the dividing step 1004 to be conducted afterwards, and, therefore, in the protective film removing step 1003, a laser beam 32 of such a wavelength as to be absorbed in the protective film 120 (resin 22) and the wafer 100 is applied, to not only remove the protective film 120 on the division lines 103 but also remove surface layer parts on the division lines 103 of the semiconductor substrate 101, thereby removing the TEG.

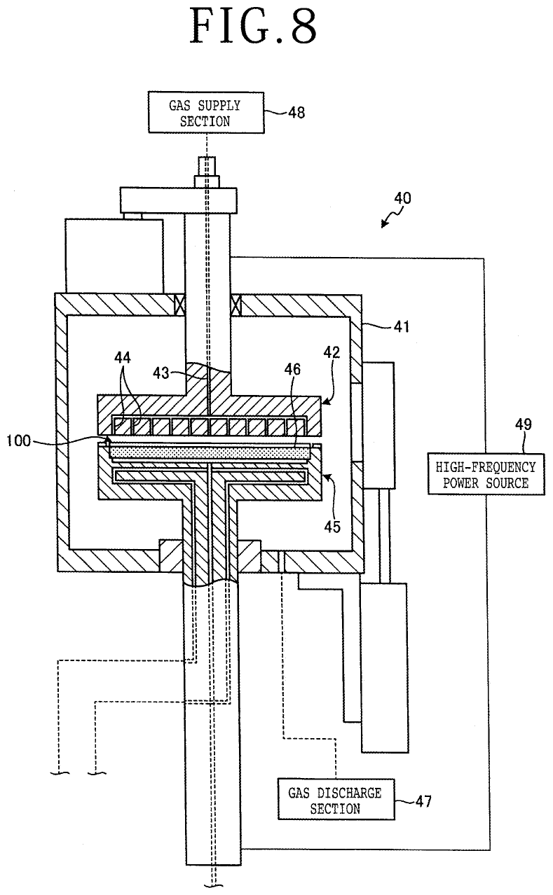

The dividing step 1004 is a step in which, as depicted in FIGS. 6 and 8, after the protective film removing step 1003, the semiconductor substrate 101 exposed along the division lines 103 is subjected to plasma etching, with the protective film 120 covering the devices 104 as a shielding film (mask), by a plasma etching apparatus 40, to thereby divide the wafer 100.

In the dividing step 1004, as depicted in FIG. 8, the wafer 100 after the protective film removing step 1003 is conveyed into a chamber 41 of the plasma etching apparatus 40, and the back surface 107 side of the wafer 100 is held on a holding surface 46 of a holding table 45 through the adhesive tape 108. The holding table 45 is similar in structure to the holding table 15. In the dividing step 1004, next, the space inside the chamber 41 is hermetically sealed and then evacuated by a gas discharge section 47.

In the dividing step 1004, thereafter, etching gas supply means 42 of the plasma etching apparatus 40 is lowered such that a lower surface of the etching gas supply means 42 faces the front surface 102 of the wafer 100 on the holding surface 45, an etching gas is supplied from a gas supply section 48 to a gas flow hole 43, and the etching gas is jetted from jet sections 44 at the lower surface of the etching gas supply means 42. In the dividing step 1004, then, a high-frequency voltage is impressed between the etching gas supply means 42 and the holding table 45 from a high-frequency power source 49, to plasmatize the etching gas jetted from the jet sections 44. In the dividing step 1004, in addition, a bias voltage is impressed on the wafer 100 to draw ions in the plasma to the front surface 102 of the wafer 100, and those parts of the semiconductor substrate 101 which are exposed along the division lines 103 are selectively etched. In the dividing step, as a result, as depicted in FIG. 6, etching grooves 130 in a depth corresponding to the thickness of the semiconductor substrate 101 are formed along the division lines 103, and the wafer 100 is divided into individual device chips having the respective devices 104 by the etching grooves 130. In the dividing step 1004, half cutting in which such etching grooves 130 as not to completely divide the wafer 100 are formed may be adopted.

The etching gas used in the dividing step 1004, in the present embodiment in which the semiconductor substrate 101 formed thereon with the devices 104 is a silicon substrate, is a fluorine-based gas (fluorine-based stable gas) for suitably etching the silicon substrate, and includes, for example, at least any of sulfur hexafluoride (SF₆), carbon tetrafluoride (CF₄), ethane hexafluoride (C₂F₆), tetrafluoroethylene (C₂F₄), octafluorocyclobutane (C₄F₈), and trifluoromethane (CHF₃). Note that the etching gas is not limited to this example in the present invention, and gases of various compounds are used according to the base material of the semiconductor substrate 101, the passivation film 106, and the like.

The plasma etching apparatus used in the dividing step 1004 is not limited to the form of the above-described plasma etching apparatus 40 in the present invention, and may be what is generally called a remote plasma type plasma etching apparatus in which the etching gas is plasmatized outside the chamber and the plasmatized etching gas is supplied into the chamber.

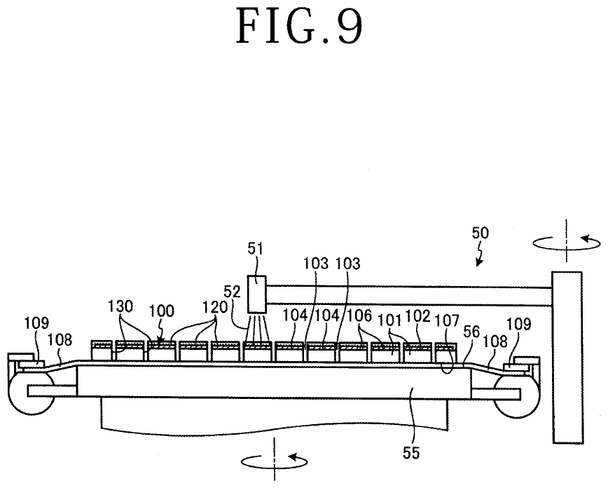

The protective film cleaning step 1005 is a step in which, as depicted in FIGS. 6 and 9, the protective film 120 coating the devices 104 is cleaned with cleaning water 52 and removed by a cleaning apparatus 50, after the dividing step 1004.

In the protective film cleaning step 1005, first, the back surface 107 side of the wafer 100 is held on a holding surface 56 of a holding table 55 of the cleaning apparatus 50 through the adhesive tape 108. The holding table 55 is similar in structure to the holding table 15. In the protective film cleaning step 1005, next, as depicted in FIG. 9, during rotation of the holding table 55 holding the wafer 100 thereon, cleaning water 52 is supplied by a nozzle 51 of the cleaning apparatus 50 to the vicinity of the center of the front surface 102 of the wafer 100, so that the cleaning water 52 thus supplied is spread to the whole area of the front surface 102 of the wafer 100 by a centrifugal force at the time of rotation of the holding table 55. In the protective film cleaning step 1005, the cleaning water 52 spread to the whole area of the front surface 102 of the wafer 100 dissolves the water-soluble protective film 120 on the front surface 102 of the wafer 100 or undergoes a chemical reaction with the protective film 120, to thereby remove the protective film 120 formed on the front surface 102 of the wafer 100. The cleaning water 52 used in the protective film cleaning step 1005 is water such as pure water in the present embodiment in which the protective film 120 is formed from the water-soluble resin 22, but, in the present invention, this is not limitative. Various liquids for cleaning are used according to chemical properties of the resin 22.

The wafer processing method according to the embodiment configured as above, after the removal of the passivation film 106 on the division lines 103 in the passivation film removing step 1001, forms the protective film 120 in the protective film forming step 1002 and removes the protective film 120 on the division lines 103 in the protective film removing step 1003. Therefore, the wafer processing method has an effect that the possibility that the laser beam 12 may be scattered by the protective film 120 at the time of removing the passivation film 106 and unintended regions of the passivation film 106 may be processed and peeled off by the scattered light can be restrained. In addition, the wafer processing method according to the embodiment removes the passivation film 106 on the division lines 103 and thereafter forms and removes the protective film 120, and, therefore, has an effect that the possibility that light transmitted through the water-soluble protective film 120 to be applied to the passivation film 106 may process and peel off unintended regions of the passivation film 106 can be restrained.

The wafer processing method according to the embodiment uses the water-soluble resin as the liquid resin 22 in the protective film forming step 1002, and cleans with water and removes the protective film 120 of the resin 22 coating the devices 104 in the protective film cleaning step 1005 that is carried out after the dividing step 1004, and, therefore, the protective film 120 can be formed and removed efficiently.

In the wafer processing method according to the embodiment, the semiconductor substrate 101 of the wafer 100 is a silicon substrate, the passivation film 106 is any of an SiO₂ film, a nitride film, and a polyimide film, and plasma etching is conducted using a fluorine-based gas in the dividing step 1004, and, therefore, exposed parts of the semiconductor substrate 101 can efficiently be plasma etched, while sufficiently maintaining the function of the passivation film 106 such as protection of the devices 104.

Note that it is preferable that the processed grooves 129 by the laser beam 32 in the protective film removing step 1003 are narrower than the processed grooves 119 by the laser beam 12 in the passivation film removing step 1001. As a result, there is produced an effect that the passivation film 106 is less liable to be peeled off by the scattered light of the laser beam 32 or heat in removing the protective film 120.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A wafer processing method for dividing a wafer including a semiconductor substrate having a plurality of devices formed on a front surface thereof in regions partitioned by a plurality of intersecting division lines, into individual device chips, the semiconductor substrate having a passivation film laminated on the front surface thereof, the wafer processing method comprising:
a passivation film removing step of applying a laser beam to the division lines to remove the passivation film laminated on the division lines and expose the semiconductor substrate along the division lines;
a protective film forming step of coating the front surface of the wafer with a resin to form a protective film, after the passivation film removing step;
a protective film removing step of applying a laser beam to the division lines to remove the protective film laminated on the division lines and expose the semiconductor substrate along the division lines, after the protective film forming step; and
a dividing step of dividing the semiconductor substrate exposed along the division lines by plasma etching with the protective film coating the devices as a shielding film, after the protective film removing step.

2. The wafer processing method according to claim 1,
wherein the resin that is in a liquid form and used in the protective film forming step is a water-soluble resin, and
the wafer processing method further comprises a protective film cleaning step of cleaning with water and removing the protective film coating the devices, after the dividing step.

3. The wafer processing method according to claim 1,
wherein the passivation film is any of an SiO₂ film, a nitride film, and a polyimide film,
the semiconductor substrate is a silicon substrate, and
a gas used in the plasma etching is a fluorine-based gas.
